(19) United States
(12) Patent Application Publication
(10) Pub. No.: US 2026/0157191 A1
(43) Pub. Date: Jun. 4, 2026

(54) SEMICONDUCTOR DEVICE AND MANUFACTURING METHOD THEREOF

(71) Applicant: FUJI ELECTRIC CO., LTD., Kawasaki-shi (JP)

(72) Inventor: Akihiro OSAWA, Matsumoto-city (JP)

(73) Assignee: FUJI ELECTRIC CO., LTD., Kawasaki-shi (JP)

(21) Appl. No.: 19/373,433

(22) Filed: Oct. 29, 2025

(30) Foreign Application Priority Data
Dec. 3, 2024 (JP) 2024-210764

(51) Int. Cl. H10W 70/40; H10W 70/20; H10W 76/15

(52) U.S. Cl. CPC H10W 70/464; H10W 70/20; H10W 76/15

(57) ABSTRACT

A semiconductor device, including: a case having a frame shape in a plan view, an inner surface of the case surrounding a storage area; a conductive plate disposed in the storage area; and a terminal extending in an extending direction from the case to the storage area. The terminal has: a connection portion fixed to the case, and a bonding portion bonded to the conductive plate. The bonding portion includes: a bonding part having indentations on an upper surface thereof, and a low-rigidity part adjacent to the bonding part and being located between the bonding part and the inner surface. A thickness of the bonding portion decreases at the low-rigidity part and further decreases at the bonding part in the extending direction. In the plan view, the bonding part has a width larger than a width of a remaining portion of the bonding portion excluding the bonding part.

### CROSS-REFERENCE TO RELATED APPLICATION

This application is based upon and claims the benefit of priority of the prior Japanese Patent Application No. 2024-210764, filed on December 3, 2024, the entire contents of which are incorporated herein by reference.

### BACKGROUND OF THE INVENTION

### Field of the Invention

The embodiment discussed herein relates to a semiconductor device and a manufacturing method thereof.

### Background of the Related Art

A semiconductor device includes a semiconductor chip, an insulated circuit board on which the semiconductor chip is provided, and a case in which the semiconductor chip and the insulated circuit board are stored and with which an external connection terminal is integrally formed. In the case, the external connection terminal is electrically connected to a conductive plate included in the insulated circuit board (see, for example, Japanese Laid-open Patent Publication No. 2022-189515 and Japanese Laid-open Patent Publication No. 2017-139304).

### SUMMARY OF THE INVENTION

According to an aspect of the present disclosure, there is provided a semiconductor device including: a case having a frame shape in a plan view of the semiconductor device, an inner surface of the case surrounding a storage area; a conductive plate disposed in the storage area; and a terminal extending in an extending direction from the case to the storage area, the terminal having a connection portion fixed to the case, and a bonding portion bonded to the conductive plate, wherein the bonding portion includes: a bonding part having indentations on an upper surface thereof, and a low-rigidity part adjacent to the bonding part, the low-rigidity part being located between the bonding part and the inner surface, a thickness of the bonding portion decreases at the low-rigidity part and further decreases at the bonding part in the extending direction, and in the plan view, the bonding part has a width larger than a width of a remaining portion of the bonding portion excluding the bonding part.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to an embodiment;

FIG. 2 is a cross-sectional view of the semiconductor device according to the embodiment;

FIG. 3 is a plan view of a semiconductor unit included in the semiconductor device according to the embodiment;

FIG. 4 is a side view of the semiconductor unit included in the semiconductor device according to the embodiment;

FIG. 5 is a side view of the semiconductor device according to the embodiment;

FIG. 6 is a cross-sectional view of a bonding part of a connection terminal of the semiconductor device according to the embodiment;

FIG. 7 is a plan view of the bonding part of the connection terminal of the semiconductor device according to the embodiment;

FIG. 8 is a flowchart of a manufacturing method of the semiconductor device according to the embodiment;

FIG. 9 is a cross-sectional view of the connection terminal included in a case of the semiconductor device according to the embodiment;

FIG. 10 is a plan view of the connection terminal included in the case of the semiconductor device according to the embodiment;

FIG. 11 is a cross-sectional view illustrating a case attachment step in the manufacturing method of the semiconductor device according to the embodiment;

FIG. 12 is a plan view illustrating the case attachment step in the manufacturing method of the semiconductor device according to the embodiment;

FIG. 13 is a cross-sectional view illustrating a first wiring step (before bonding) in the manufacturing method of the semiconductor device according to the embodiment;

FIG. 14 is a cross-sectional view illustrating the first wiring step (during bonding) in the manufacturing method of the semiconductor device according to the embodiment;

FIG. 15 is a cross-sectional view (before bonding) illustrating a first wiring step in a manufacturing method of a semiconductor device according to a reference example; and

FIG. 16 is a cross-sectional view (during bonding) illustrating the first wiring step in the manufacturing method of the semiconductor device according to the reference example.

### DETAILED DESCRIPTION OF THE INVENTION

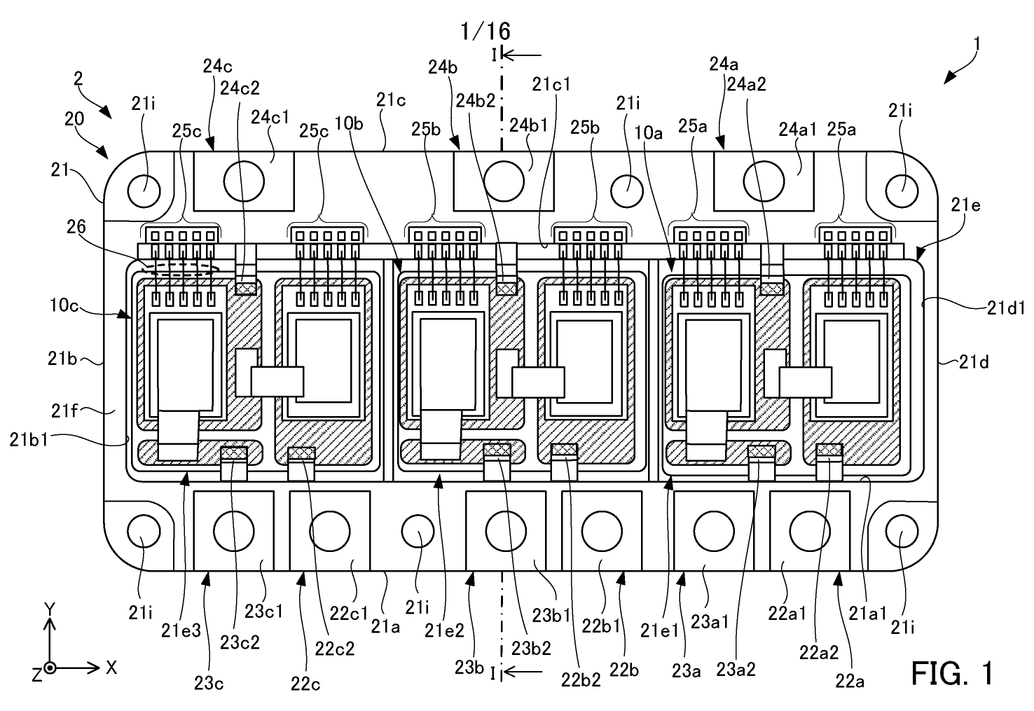

Hereinafter, an embodiment will be described with reference to the drawings. In the following description, a “front surface” and an “upper surface” represent an X-Y plane facing upward (+Z direction) in a semiconductor device 1 in FIGS. 1, 2, and 5. Similarly, the term “upper” indicates an upward direction (+Z direction) in the semiconductor device 1 in FIGS. 1, 2, and 5. The “back surface” and the “lower surface” represent an X-Y plane facing downward (−Z direction) in the semiconductor device 1 in FIGS. 1, 2, and 5. Similarly, the term “lower” indicates a downward direction (−Z direction) in the semiconductor device 1 in FIGS. 1, 2, and 5. The same directionality as described above is meant in the other drawings, as needed. The terms “higher” and “upper” indicate positions on the upper side (+Z direction) in the semiconductor device 1 in FIGS. 1, 2, and 5. Similarly, “lower” indicates positions on the lower side (−Z direction) in the semiconductor device 1 in FIGS. 1, 2, and 5. The terms “front surface”, “upper surface”, “upper” and “back surface”, “lower surface”, “lower” and “side surface” are merely convenient expressions for determining relative positional relationships, and do not limit the technical idea of the present embodiment. For example, “upper” and “lower” may mean directions other than the vertical directions with respect to the ground. That is, the “upper” and “lower” directions are not limited to the gravity directions. In addition, in the following description, “main component” represents a case where 80vol% or more is contained. Further, “substantially the same” may be within a range of ±10%. In addition, “perpendicular”, “orthogonal”, and “parallel” may be within a range of ±10°.

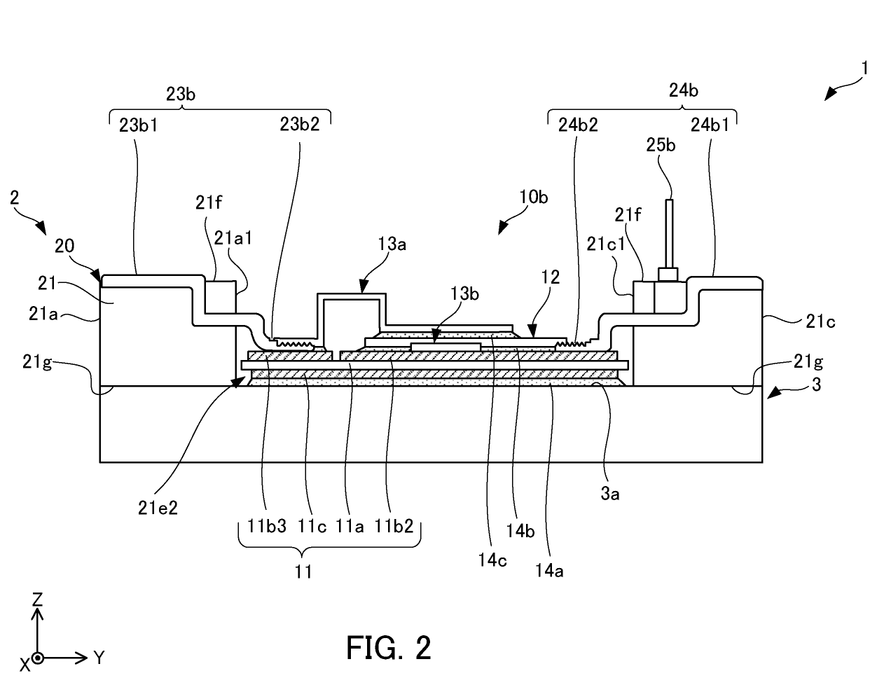

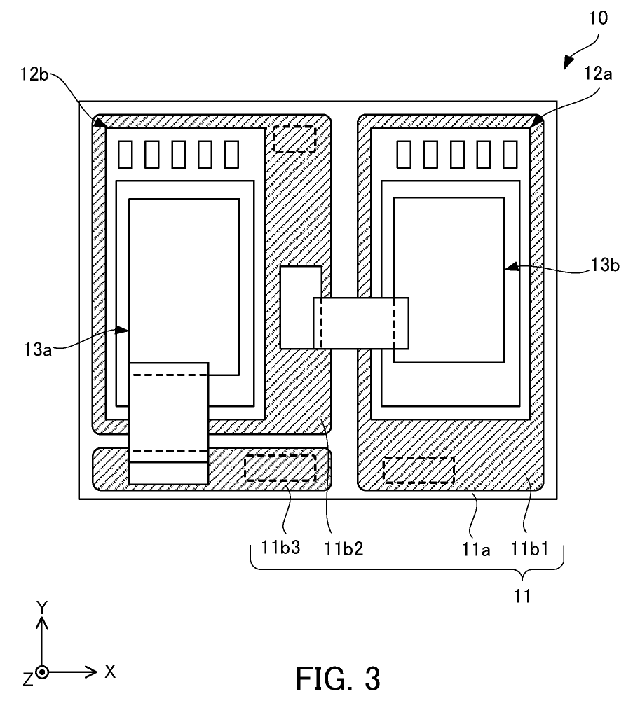

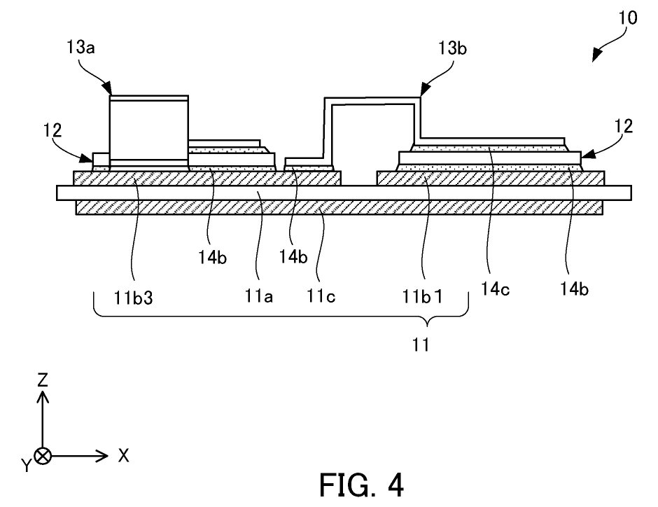

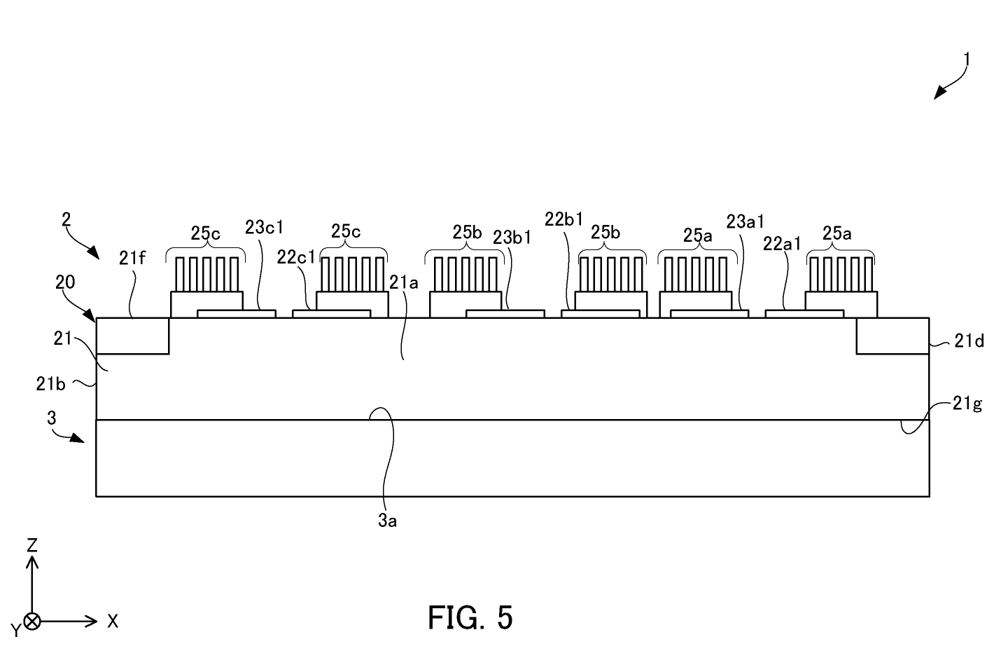

A semiconductor device 1 according to an embodiment will be described with reference to FIGS. 1 to 5. FIG. 1 is a plan view of a semiconductor device according to an embodiment. FIG. 2 is a cross-sectional view of the semiconductor device according to the embodiment. FIG. 3 is a plan view of a semiconductor unit included in the semiconductor device according to the embodiment. FIG. 4 is a side view of the semiconductor unit included in the semiconductor device according to the embodiment. FIG. 5 is a side view of the semiconductor device according to the embodiment.

FIG. 2 is a cross-sectional view taken along a dashed-dotted line I-I in FIG. 1. FIG. 4 is a side view (Y-X plane) of a semiconductor unit 10 in FIG. 3, as viewed in the +Y direction. FIG. 5 is a side view (Y-X plane) of the semiconductor device 1 in FIG. 1, as viewed in the +Y direction. In FIGS. 1 and 2, a sealing member is not illustrated. Unit storage portions 21e1, 21e2, and 21e3 of a case 20 may each be filled with a sealing member.

The semiconductor device 1 includes a semiconductor module 2 and a cooling module 3. The semiconductor module 2 includes semiconductor units 10a, 10b, and 10c, and the case 20 that stores the semiconductor units 10a, 10b, and 10c. The semiconductor units 10a, 10b, and 10c stored in the case 20 are sealed by a sealing member (not illustrated).

The semiconductor units 10a, 10b, and 10c have the same construction. When the semiconductor units 10a, 10b, and 10c are not distinguished from each other, any one of the semiconductor units 10a, 10b, and 10c will be described as a semiconductor unit 10. Details of these semiconductor units 10 will be described below.

The case 20 includes a frame portion 21, first connection terminals 22a, 22b, and 22c, second connection terminals 23a, 23b, and 23c, a W-phase output terminal 24a, a V-phase output terminal 24b, a U-phase output terminal 24c, and control terminals 25a, 25b, and 25c.

The frame portion 21 has an approximately rectangular shape in plan view. The frame portion 21 includes outer walls 21a, 21b, 21c, and 21d sequentially constituting four sides, and inner walls 21a1, 21b1, 21c1, and 21d1 opposite to the outer walls 21a, 21b, 21c, and 21d, respectively. Further, the frame portion 21 includes an upper surface 21f and a lower surface 21g connected to the outer walls 21a, 21b, 21c, and 21d and the inner walls 21a1, 21b1, 21c1, and 21d1. The outer walls 21a and 21c and the inner walls 21a1 and 21c1 extend in the longitudinal direction, corresponding to the long sides of the frame portion 21. The outer walls 21b and 21d and the inner walls 21b1 and 21d1 extend in the lateral direction, corresponding to the short sides of the frame portion 21. In addition, corner portions, each of which is a connection portion where two of the outer walls 21a, 21b, 21c, and 21d meet, may have a right angle or an angle other than a right angle. Similarly, corner portions, each of which is a connection portion where two of the inner walls 21a1, 21b1, 21c1, and 21d1 meet, may have a right angle or an angle other than a right angle. These corner portions may be rounded as illustrated in FIG. 1. Fastening holes 21i penetrating the frame portion 21 in the ±Z directions may be formed in the corner portions of the upper surface 21f and the lower surface 21g of the frame portion 21.

The frame portion 21 includes an opening 21e sequentially surrounded by the inner walls 21a1, 21b1, 21c1, and 21d1 in four directions. That is, the opening 21e has a rectangular shape in plan view and is defined by the inner walls 21a1, 21b1, 21c1, and 21d1 (inner surfaces). The opening 21e opens from the upper surface 21f to the lower surface 21g of the frame portion 21.

The opening 21e of the frame portion 21 further includes the unit storage portions 21e1, 21e2, and 21e3 in which the semiconductor units 10a, 10b, and 10c are stored. The unit storage portions 21e1, 21e2, and 21e3 are provided sequentially along the outer walls 21a and 21c and the inner walls 21a1 and 21c1 in the opening 21e by partitioning the opening 21e into three portions in plan view. A step may be provided on the inner wall 21c1 opposite to the outer wall 21c at the unit storage portions 21e1, 21e2, and 21e3.

The semiconductor units 10a, 10b, and 10c are each bonded to a cooling surface 3a of the cooling module 3 by a bonding member 14a. When the frame portion 21 is attached to the cooling surface 3a of the cooling module 3, the semiconductor units 10a, 10b, and 10c are stored in the unit storage portions 21e1, 21e2, and 21e3 of the frame portion 21, respectively. The frame portion 21 may be bonded to the cooling surface 3a of the cooling module 3 with an adhesive (not illustrated).

The frame portion 21 includes the positive first connection terminals 22a, 22b, and 22c and the negative second connection terminals 23a, 23b, and 23c near the outer wall 21a in plan view. The first connection terminals 22a, 22b, and 22c include connection portions 22a1, 22b1, and 22c1, respectively, on one side, and also include bonding portions 22a2, 22b2, and 22c2, respectively, on the other side. Similarly, the second connection terminals 23a, 23b, and 23c include connection portions 23a1, 23b1, and 23c1, respectively, on one side, and also include bonding portions 23a2, 23b2, and 23c2, respectively, on the other side.

The connection portions 22a1, 22b1, and 22c1 and the connection portions 23a1, 23b1, and 23c1 on one side are disposed on the upper surface 21f near the outer wall 21a. An opening hole may be formed in each of these connection portions (reference characters are omitted). In the upper surface 21f of the frame portion 21 on which the connection portions are disposed, nuts may be stored so as to face the opening holes of their respective connection portions.

The bonding portions 22a2, 22b2, and 22c2 and the bonding portions 23a2, 23b2, and 23c2 on the other side extend into the unit storage portions 21e1, 21e2, and 21e3, and are electrically connected to the semiconductor units 10a, 10b, and 10c, respectively.

A part of the intermediate portion between the connection portion and the bonding portion of each of the first connection terminals 22a, 22b, and 22c and the second connection terminals 23a, 23b, and 23c is included in the frame portion 21, and the rest is exposed to the unit storage portions 21e1, 21e2, and 21e3 of the frame portion 21. The first connection terminals 22a, 22b, and 22c and the second connection terminals 23a, 23b, and 23c may have the same construction . Details of the first connection terminals 22a, 22b, and 22c and the second connection terminals 23a, 23b, and 23c will be described below.

The frame portion 21 includes the W-phase output terminal 24a, the V-phase output terminal 24b, and the U-phase output terminal 24c near the outer wall 21c in plan view. The W-phase output terminal 24a, the V-phase output terminal 24b, and the U-phase output terminal 24c include connection portions 24a1, 24b1, and 24c1, respectively, on one side, and also include bonding portions 24a2, 24b2, and 24c2, respectively, on the other side.

The connection portions 24a1, 24b1, and 24c1 on one side are disposed on the upper surface 21f near the outer wall 21c. An opening hole may be formed in these connection portions. In the upper surface 21f of the frame portion 21 on which these connection portions are disposed, nuts may be stored so as to face the opening holes of their respective connection portions.

The bonding portions 24a2, 24b2, and 24c2 on the other side extend into the unit storage portions 21e1, 21e2, and 21e3, respectively, and are electrically connected to the semiconductor units 10a, 10b, and 10c, respectively. A part of the intermediate portion between the connection portion and the bonding portion of each of the W-phase output terminal 24a, the V-phase output terminal 24b, and the U-phase output terminal 24c is included in the frame portion 21, and the rest is exposed to the unit storage portions 21e1, 21e2, and 21e3 of the frame portion 21. The W-phase output terminal 24a, the V-phase output terminal 24b, and the U-phase output terminal 24c may have the same construction.

Therefore, the frame portion 21 includes the first connection terminal 22a and the second connection terminal 23a near the outer wall 21a, and includes the W-phase output terminal 24a near the outer wall 21c, with the unit storage portion 21e1 interposed therebetween in plan view. Similarly, the frame portion 21 includes the first connection terminal 22b and the second connection terminal 23b near the outer wall 21a, and includes the V-phase output terminal 24b near the outer wall 21c, with the unit storage portion 21e2 interposed therebetween in plan view. Similarly, the frame portion 21 includes the first connection terminal 22c and the second connection terminal 23c near the outer wall 21a, and includes the U-phase output terminal 24c near the outer wall 21c, with the unit storage portion 21e3 interposed therebetween in plan view.

On the upper surface 21f near the outer wall 21c, the control terminals 25a, 25b, and 25c are provided along the outer wall 21c for the unit storage portions 21e1, 21e2, and 21e3, respectively. One end of each of the control terminals 25a, 25b, and 25c extends in the +Z direction from the upper surface 21f. The other end portion is exposed from the step of the inner wall 21c1 to a corresponding one of the unit storage portions 21e1, 21e2, and 21e3, and is electrically connected to a control electrode of a semiconductor chip to be described below via, for example, a wire 26. The wire 26 contains a material having excellent electrical conductivity as its main component. This material is, for example, gold, copper, aluminum, or an alloy containing at least one of these metals. Preferably, the wire 26 may be an aluminum alloy containing a trace amount of silicon.

The first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c are made of a metal having excellent electrical conductivity. This metal is, for example, copper, aluminum, or an alloy containing at least one of these metals as its main component. The surfaces of the first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c may be plated. In this case, the plating material used is, for example, nickel, a nickel-phosphorus alloy, or a nickel-boron alloy.

The frame portion 21 includes the first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c, and is integrally molded by injection molding using a thermoplastic resin. Examples of the thermoplastic resin include polyphenylene sulfide resin, polybutylene terephthalate resin, polybutylene succinate resin, polyamide resin, and acrylonitrile butadiene styrene resin.

The sealing member that seals the unit storage portions 21e1, 21e2, and 21e3 of the frame portion 21 may be a silicone gel or a thermosetting resin. Examples of the thermosetting resin include an epoxy resin, a phenol resin, a maleimide resin, and a polyester resin. Although the sealing member entirely seals the semiconductor units 10a, 10b, and 10c stored in the unit storage portions 21e1, 21e2, and 21e3, the sealing member does not need to seal the unit storage portions 21e1, 21e2, and 21e3 entirely. It is desirable that portions of the first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c, the portions being exposed to the unit storage portions 21e1, 21e2, and 21e3, be sealed.

The individual semiconductor unit 10 may be a device constituting an inverter circuit for one phase. The individual semiconductor unit 10 includes an insulated circuit board 11, semiconductor chips 12a and 12b, and lead frames 13a and 13b. The semiconductor chips 12a and 12b are bonded to the insulated circuit board 11 by a bonding member 14b. The lead frames 13a and 13b are bonded to the main electrodes on the upper surfaces of the semiconductor chips 12a and 12b and the upper surface of the insulated circuit board 11 by a bonding member 14c. The lead frames 13a and 13b may be bonded to the insulated circuit board 11 by ultrasonic bonding, instead of the bonding member 14c.

The insulated circuit board 11 includes an insulating plate 11a, conductive circuit patterns 11b1, 11b2, and 11b3, and a metal plate 11c. The insulating plate 11a has a rectangular shape in plan view. The insulating plate 11a may have rounded or chamfered corner portions.

The insulating plate 11a is made of a material having an insulating property and excellent thermal conductivity. The insulating plate 11a may be made of a ceramic material. The ceramic material is, for example, aluminum oxide, aluminum nitride, or silicon nitride.

Alternatively, the insulating plate 11a may be made of a resin. The resin may be a material having low thermal resistance and a high insulating property. Examples of the resin include a thermosetting resin and a thermoplastic resin. The resin may further contain a filler. Examples of the thermosetting resin include at least one of an epoxy resin, a cyanate resin, a benzoxazine resin, an unsaturated polyester resin, a phenol resin, a melamine resin, a silicone resin, and a maleimide resin. Examples of the thermoplastic resin include at least one of a polyimide resin, an acrylic resin, and a polyamide resin. The filler is made of at least one of an oxide and a nitride. Examples of the oxide include silicon oxide and aluminum oxide. Examples of the nitride include silicon nitride, aluminum nitride, and boron nitride. Further, hexagonal boron nitride may be used as the filler.

The conductive circuit patterns 11b1, 11b2, and 11b3 are each an example of a conductive plate, and are formed on the front surface of the insulating plate 11a. The conductive circuit patterns 11b1, 11b2, and 11b3 are made of a metal having excellent electrical conductivity. This metal is, for example, copper, aluminum, or an alloy containing at least one of these metals as its main component. The surfaces of the conductive circuit patterns 11b1, 11b2, and 11b3 may be plated to improve corrosion resistance. In this case, the plating material used is, for example, nickel, a nickel-phosphorus alloy, or a nickel-boron alloy.

The conductive circuit pattern 11b1 is a half area on the +X direction side of the front surface of the insulating plate 11a, and entirely occupies this area from the −Y direction side to the +Y direction side. A corresponding one of the bonding portions 22a2, 22b2, and 22c2 of the first connection terminals 22a, 22b, and 22c is bonded to the area surrounded by a broken line on the conductive circuit pattern 11b1. These may be bonded by ultrasonic bonding.

The conductive circuit pattern 11b2 occupies the other half of the front surface of the insulating plate 11a on the −X direction side. Specifically, the conductive circuit pattern 11b2 occupies an area of the front surface of the insulating plate 11a, the area from the +Y direction side to a portion a little before the −Y direction side. The conductive circuit pattern 11b2 is bonded to a corresponding one of the bonding portions 24a2, 24b2, and 24c2 of the W-phase output terminal 24a, the V-phase output terminal 24b, and the U-phase output terminal 24c. These may be bonded by ultrasonic bonding.

The conductive circuit pattern 11b3 is in the half area on the −X direction side of the front surface of the insulating plate 11a, and is provided on the −Y direction side. That is, the conductive circuit pattern 11b3 occupies the area other than the conductive circuit patterns 11b1 and 11b2 on the upper surface of the insulating plate 11a. A corresponding one of the bonding portions 23a2, 23b2, and 23c2 of the second connection terminals 23a, 23b, and 23c is bonded to the area surrounded by a broken line on the conductive circuit pattern 11b3. These may be bonded by ultrasonic bonding.

The metal plate 11c is formed on the lower surface of the insulating plate 11a. The metal plate 11c has a rectangular shape. The area of the metal plate 11c in plan view is smaller than the area of the insulating plate 11a and is larger than the area where the conductive circuit patterns 11b1, 11b2, and 11b3 are formed. The metal plate 11c may have rounded or chamfered corner portions. The metal plate 11c is formed on the entire surface of the insulating plate 11a, except for the edge portion thereof. The metal is, for example, copper, aluminum, or an alloy containing at least one of these metals. Plating may be performed on the surface of the metal plate 11c in order to improve the corrosion resistance. In this case, the plating material used is, for example, nickel, a nickel-phosphorus alloy, or a nickel-boron alloy.

When the insulating plate 11a is made of a ceramic material, for example, a direct copper bonding (DCB) substrate or an active metal brazed (AMB) substrate may be used as the insulated circuit board 11. The insulated circuit board 11 may be attached to the cooling surface 3a of the cooling module 3 via a bonding member 14a. The heat generated by the semiconductor chips 12a and 12b is conducted to the cooling module 3 via the conductive circuit patterns 11b1 and 11b2, the insulating plate 11a, and the metal plate 11c, and is consequently radiated.

The bonding member 14a may be a brazing material or a thermal interface material. The brazing material contains, for example, at least one of an aluminum alloy, a titanium alloy, a magnesium alloy, a zirconium alloy, and a silicon alloy as its main component. Examples of the thermal interface material include various materials such as thermally conductive grease, elastomer sheet, room temperature vulcanization (RTV) rubber, gel, and phase change material. By attaching the individual semiconductor unit 10 to the cooling module 3 via the brazing material or thermal interface material as described above, the heat dissipation of the individual semiconductor unit 10 is improved.

The bonding members 14b and 14c may be solder. As the solder, lead-free solder is used. The lead-free solder contains, for example, an alloy containing at least two of tin, silver, copper, zinc, antimony, indium, and bismuth as its main component. Further, the solder may contain an additive. The additive is, for example, nickel, germanium, cobalt, or silicon. When the solder contains an additive, the wettability, gloss, and bonding strength are improved, and reliability is consequently improved. In particular, a sintered body may be used as the bonding member 14a. When the bonding is performed by a sintered body, the sintered material is, for example, powder of silver, iron, copper, aluminum, titanium, nickel, tungsten, or molybdenum.

The semiconductor chips 12a and 12b include a power device element made mainly of silicon. The power device element is a reverse-conducting insulated gate bipolar transistor (RC-IGBT). The RC-IGBT has both functions of an IGBT, which is a switching element, and a freewheeling diode (FWD), which is a diode element. Control electrodes (gate electrodes and the like) and output electrodes (emitter electrodes) as main electrodes are provided on the upper surfaces of the semiconductor chips 12a and 12b. Input electrodes (collector electrodes), which are main electrodes, are provided on the lower surfaces of the semiconductor chips 12a and 12b. The control electrodes may be provided along one side of the upper surface of each of the semiconductor chips 12a and 12b (or at a center portion of one side). The output electrode may be provided at a center portion of the upper surface of each of the semiconductor chips 12a and 12b. The lead frames 13a and 13b are electrically and mechanically bonded to the output electrodes of the semiconductor chips 12a and 12b.

Each of the semiconductor chips 12a and 12b may include a switching element formed of a power MOSFET made mainly of silicon carbide. Each of the semiconductor chips 12a and 12b includes a control electrode (a gate electrode or the like) and an output electrode (a source electrode) as its main electrode on its front surface. Each of the semiconductor chips 12a and 12b includes an input electrode (a drain electrode), which is a main electrode, on its back surface.

Each of the semiconductor chips 12a and 12b may use a set of a switching element and a diode element made mainly of silicon or silicon carbide. The switching element is, for example, an IGBT or a power MOSFET. Each of the semiconductor chips 12a and 12b includes, for example, an input electrode (a drain electrode or a collector electrode) as a main electrode on its back surface, and a control electrode (a gate electrode) and an output electrode (a source electrode or an emitter electrode) as a main electrode on its front surface. The diode element is, for example, an FWD such as a Schottky barrier diode (SBD) or a P-intrinsic-N (PiN) diode. Each of the semiconductor chips 12a and 12b includes an output electrode (a cathode electrode) as a main electrode on its back surface and an input electrode (an anode electrode) as a main electrode on its front surface.

The lead frames 13a and 13b electrically connect and wire the semiconductor chips 12a and 12b and the conductive circuit patterns 11b2 and 11b3. The lead frame 13a directly connects a main electrode of the semiconductor chip 12b and the conductive circuit pattern 11b3 via a bonding member 14c. The lead frame 13b directly connects a main electrode of the semiconductor chip 12a and the conductive circuit pattern 11b2 via a bonding member 14c. The lead frames 13a and 13b may be bonded to the conductive circuit patterns 11b3 and 11b2 by ultrasonic bonding.

The lead frames 13a and 13b are made of a metal having excellent electrical conductivity. The metal is, for example, copper, aluminum, or an alloy containing at least one of these metals as its main component. The surfaces of the lead frames 13a and 13b may be plated to improve corrosion resistance. In this case, the plating material used is, for example, nickel, a nickel-phosphorus alloy, or a nickel-boron alloy.

The cooling module 3 includes, on its front side, the cooling surface 3a on which the semiconductor module 2 is disposed. Specifically, as described above, the frame portion 21 is attached to the cooling surface 3a of the cooling module 3 on which the semiconductor units 10a, 10b, and 10c are disposed. The cooling surface 3a is wider than the back surface of the semiconductor module 2 and is flat. The cooling module 3 may be, for example, a heat dissipation base including heat dissipation fins or a cooling device in which a refrigerant circulates.

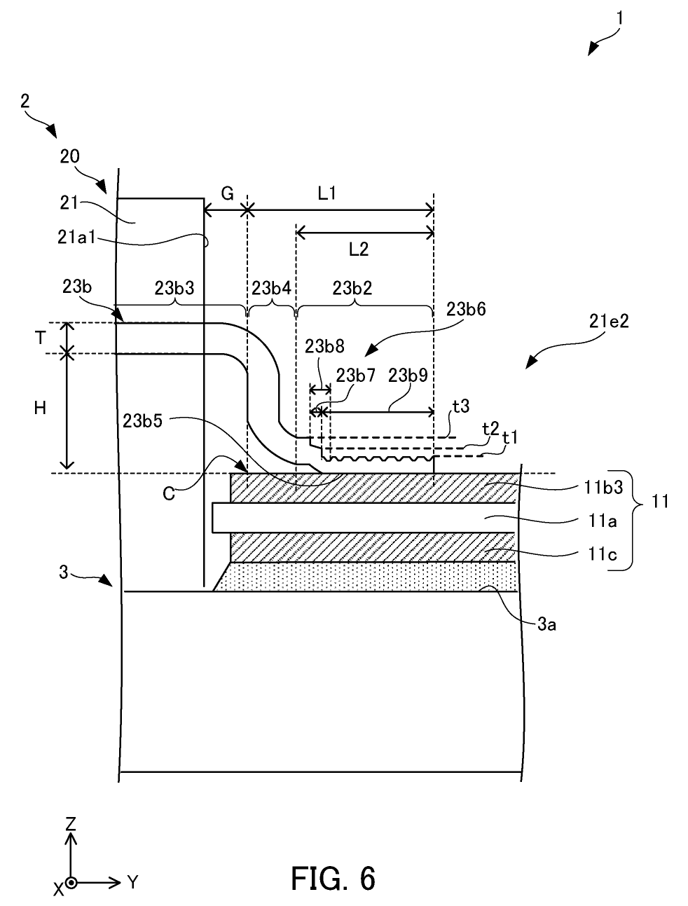

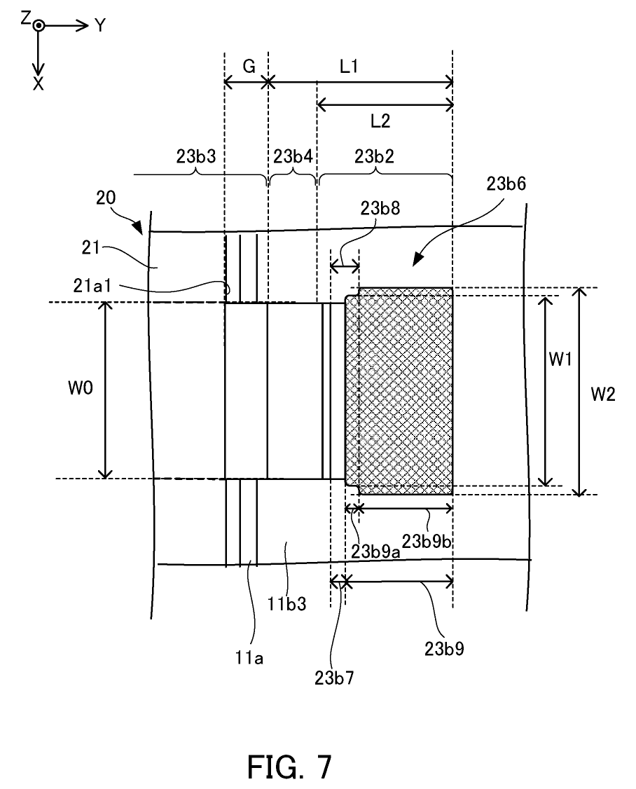

Next, the first connection terminals 22a, 22b, and 22c and the second connection terminals 23a, 23b, and 23c will be described in detail. As described above, the first connection terminals 22a, 22b, and 22c and the second connection terminals 23a, 23b, and 23c have the same construction. Hereinafter, as an example, the second connection terminal 23b will be described with reference to FIGS. 6 and 7.

FIG. 6 is a cross-sectional view of a bonding part of a connection terminal of the semiconductor device according to the embodiment. FIG. 7 is a plan view of the bonding part of the connection terminal of the semiconductor device according to the embodiment. FIG. 6 is an enlarged view of a portion of the second connection terminal 23b in FIG. 2, the portion extending from the inner wall 21a1 of the frame portion 21 to the unit storage portion 21e2. FIG. 7 is an enlarged plan view of the second connection terminal 23b in FIG. 6. In addition, in FIGS. 6 and 7, a portion where a notch 23b8 to be described below was provided is denoted by a reference character corresponding to the notch.

The second connection terminal 23b includes the connection portion 23b1 and the bonding portion 23b2, and further integrally includes a wiring portion 23b3 and a rising portion 23b4. The second connection terminal 23b may have an approximately uniform thickness T as a whole. The thickness T may be 1.0 mm or more and 1.4 mm or less, for example, 1.2 mm.

As described above, the connection portion 23b1 is disposed on the upper surface 21f adjacent to the unit storage portion 21e2 of the frame portion 21 in plan view. The lower portion of the connection portion 23b1 may be embedded in the upper surface 21f (see FIGS. 1 and 2).

The bonding portion 23b2 extends in the extending direction (+Y direction) from the inner wall 21a1 (an inner surface) toward the unit storage portion 21e2, and has a lower surface 23b5 (a bonding surface) bonded to the conductive circuit pattern 11b3 and an upper surface 23b6 with indentations. An area of the lower surface 23b5, the area corresponding to a bonding part 23b9 described below, is bonded to the conductive circuit pattern 11b3 of the insulated circuit board 11 by ultrasonic bonding. A plurality of protrusions at a tip of a tool are transferred to the upper surface 23b6 by ultrasonic bonding, and indentations having convex and concave shapes are formed.

The bonding portion 23b2 includes a bonding part 23b9 obtained by forming indentations on the upper surface 23b6, and includes a low-rigidity part 23b7 adjacent to the bonding part 23b9 in the direction of the inner wall 21a1. The thickness of the bonding portion 23b2 decreases in the order of the low-rigidity part 23b7 and the bonding part 23b9 in the extending direction (+Y direction) from the inner wall 21a1. Further, the width of the bonding portion 23b2 is largest at the bonding part 23b9 in plan view. The width of the bonding part 23b9 will be described below. The width in the ±X directions (width direction) of the main body portion of the second connection terminal 23b, other than the bonding portion 23b2, is a width W0. The main body portion may have an approximately uniform width as a whole.

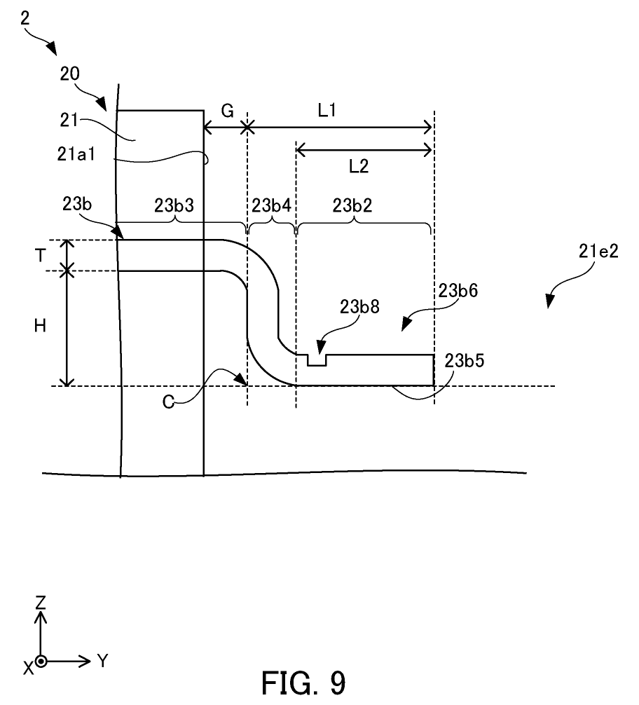

The upper surface 23b6 is pressed as described below to form the low-rigidity part 23b7 and the bonding part 23b9 with indentations. Before the low-rigidity part 23b7 and the bonding part 23b9 are formed, the upper surface 23b6 has the notch 23b8 described below (see FIG. 9). The upper surface 23b6 includes the upper surface of the notch 23b8 and a flat surface before the low-rigidity part 23b7 and the bonding part 23b9 are formed. As described below, the bonding portion 23b2 and the rising portion 23b4 are integrally connected to each other. The upper surface of the rising portion 23b4 (the side facing the +Y direction and the +Z direction in FIG. 6) forms a concave curved surface (a rounded surface) in a side view. A portion of the upper surface 23b6 of the bonding portion 23b2, the portion being connected to the rising portion 23b4, is at an end of the curved surface of the rising portion 23b4 in a side view. As to the thickness (height) of the bonding part 23b9 of the bonding portion 23b2, the bonding part 23b9 having indentations, the thickness from the lower surface 23b5 to an upper part (the top of a convex part ) is about 0.7 mm. The thickness from the lower surface 23b5 to a lower part (to the bottom of a concave part) is about 0.4 mm. The thickness of the bonding part 23b9 may be about one third of the thickness T of the second connection terminal 23b.

An edge (end) of the low-rigidity part 23b7, the edge being near the rising portion 23b4, is located within, for example, 1 mm in the extending direction (+Y direction) from the end of the curved surface of the upper surface 23b6 of the bonding portion 23b2. In FIG. 6, the end of the curved surface may be regarded as the boundary between the bonding portion 23b2 and the rising portion 23b4 (the −Y direction end of the length L2 described below).

FIG. 6 illustrates a case where the low-rigidity part 23b7 is separated in the +Y direction from the boundary between the bonding portion 23b2 and the rising portion 23b4. An area of the upper surface 23b6, the area being from the boundary between the bonding portion 23b2 and the rising portion 23b4 to an edge of the low-rigidity part 23b7, the edge being on the rising portion 23b4 side, is a flat area before the bonding part 23b9 is formed, and is not pressed when the bonding part 23b9 is formed. Therefore, this area of the upper surface 23b6 is approximately flat.

Further, the low-rigidity part 23b7 may form a step with respect to the flat area of the upper surface 23b6. That is, on the upper surface 23b6, the low-rigidity part 23b7 is located at a lower position than the flat area. The low-rigidity part 23b7 may be parallel (flat) to the +Y direction or may be inclined at an acute angle with respect to the +Y direction in a side view. FIG. 6 illustrates a case where the upper surface of the low-rigidity part 23b7 is inclined. Therefore, there is a gap between the conductive circuit pattern 11b3 and a portion corresponding to the low-rigidity part 23b7 of the bonding portion 23b2 and the boundary. The gap may be, for example, about 0.3 mm. The thickness of the low-rigidity part 23b7 is, for example, 1.0 mm.

The bonding part 23b9 is an area of the upper surface 23b6, and indentations are formed on this area. As will be described below, in ultrasonic bonding, a tool for ultrasonic bonding presses the upper surface 23b6 of the bonding portion 23b2 against the conductive circuit pattern 11b3 while vibrating ultrasonically. As a result, the bonding portion 23b2 is bonded to the conductive circuit pattern 11b3. The tool is provided with a plurality of protrusions at its tip end that presses the upper surface 23b6 of the bonding portion 23b2. The upper surface 23b6 of the bonding portion 23b2 is pressed by the plurality of protrusions of this tool, so that the convex and concave shapes of the plurality of protrusions are transferred and indentations are consequently formed. Therefore, the indentations correspond to the portion pressed by the tool on the upper surface 23b6 of the bonding portion 23b2. In addition, the tool may press the upper surface 23b6 of the bonding portion 23b2 such that part of the notch to be described below is also pressed.

In addition, the bonding part 23b9 is adjacent to the low-rigidity part 23b7 and extends from the edge of the low-rigidity part 23b7 to the tip of the bonding portion 23b2 in plan view. On the upper surface 23b6, the bonding part 23b9 has a level difference with respect to the low-rigidity part 23b7. In the upper surface 23b6, the bonding part 23b9 (the side on which the indentations are formed) is located at a lower level than (the upper side of) the low-rigidity part 23b7. The bonding part 23b9 may be separated from the low-rigidity part 23b7 in the +Y direction (extending direction). Even in this case, the bonding part 23b9 is located at a lower level than the low-rigidity part 23b7.

In the present embodiment, the bonding part 23b9 extends entirely from the edge of the low-rigidity part 23b7 to the tip of the bonding portion 23b2. Alternatively, the bonding part 23b9 may be formed to extend to a portion little before the tip of the bonding portion 23b2. In this case, the thickness and the ±X direction width of the tip where the upper surface 23b6 of the bonding portion 23b2 has not been pressed may be the thickness T and the width W0 of the main body portion.

The bonding part 23b9, which is obtained by pressing the bonding portion 23b2 with the tool, includes a first part 23b9a overlapping a part of the original cutout area and a second part 23b9b other than the first part 23b9a. The first part 23b9a is adjacent to the low-rigidity part 23b7 and is sandwiched between the low-rigidity part 23b7 and the second part 23b9b in plan view. The second part 23b9b includes the tip of the bonding portion 23b2.

The first part 23b9a and the second part 23b9b of the bonding part 23b9 have different widths (first and second widths) in the ±X directions (width direction). The width of the first part 23b9a is a width W1 (the first width). The width of the second part 23b9b is a width W2 (the second width). The width W1 is greater than the width W0 of the main body portion, and the width W2 is greater than the width W1. Therefore, on the upper surface 23b6 of the bonding portion 23b2, the width W2 of the second part 23b9b of the bonding part 23b9 > the width W1 of the first part 23b9a of the bonding part 23b9 > the width W0 of the main body portion. The width W2 of the second part 23b9b of the bonding part 23b9 is the largest in the bonding portion 23b2.

The wiring portion 23b3 is located above (in the +Z direction) the bonding portion 23b2. The wiring portion 23b3 is included in the frame portion 21, has one end connected to the connection portion 23b1, and is partially fixed to the frame portion 21. The portion of the wiring portion 23b3 included in the frame portion 21 may have, for example, a hook shape in a side view. The other end opposite to the one end of the wiring portion 23b3 extends in the +Y direction in the frame portion 21 and protrudes from the inner wall 21a1 of the frame portion 21 to the unit storage portion 21e2 perpendicularly to the inner wall 21a1.

The rising portion 23b4 connects the other end (end portion), which is the extension destination, of the wiring portion 23b3 and an end portion of the bonding portion 23b2, the end being near the inner wall 21a1. These end portions are at different heights. The inner side and the outer side of the connection portion between the upper end of the rising portion 23b4 and the extension destination end portion of the wiring portion 23b3 each form a curved surface (a rounded surface). A connection portion (a surface of the rising portion 23b4, the surface facing the inner wall 21a1) is spaced from the inner wall 21a1 by a distance G. The shortest distance between the connection portion and the tip of the bonding portion 23b2 is a length L1. The distance G may be about the thickness T of the first connection terminal 22b, and may be 1.2 mm or more and 1.7 mm or less, for example, about 1.5 mm.

Each of the inner side and the outer side of the connection portion between the lower end of the rising portion 23b4 and the end portion of the bonding portion 23b2, the end portion being in the direction of the inner wall 21a1, also forms a curved surface (a rounded surface). The shortest distance between the boundary between the rising portion 23b4 and the bonding portion 23b2 and the tip of the bonding portion 23b2 is a length L2. In plan view, the width-direction length of the rising portion 23b4 and at least a portion of the wiring portion 23b3, the portion being exposed from the inner wall 21a1, is the width W0.

At the connection portion (corner portion) between the rising portion 23b4 and the bonding portion 23b2, an intersection point of a line passing along a surface of the rising portion 23b4, the surface facing the inner wall 21a1, in the ±Z direction and a line passing along the lower surface 23b5 of the bonding portion 23b2 in the ±Y direction is set as a virtual intersection point C, and the corner portion (virtual corner portion) is configured. The length of the rising portion 23b4 in the ±Y directions (length L1 − length L2) is, for example, 2.8 mm or more and 3.2 mm or less, and may be, for example, 3.0 mm.

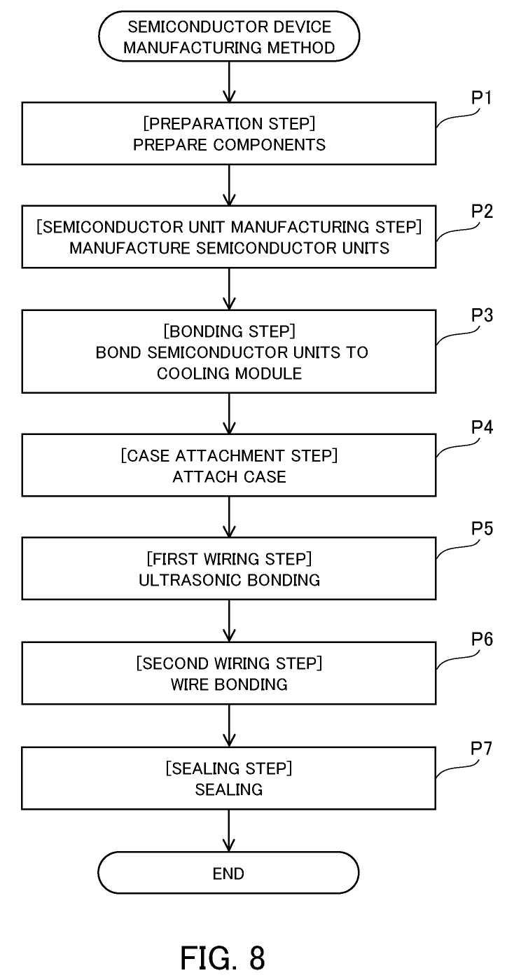

Next, a manufacturing method of the semiconductor device 1 will be described with reference to FIG. 8. FIG. 8 is a flowchart illustrating a manufacturing method of the semiconductor device according to the embodiment. First, a preparation step of preparing components of the semiconductor device 1 is performed (step P1 in FIG. 8). Examples of the prepared components include the insulated circuit board 11, the semiconductor chips 12a and 12b, the lead frames 13a and 13b, the cooling module 3, and the case 20. In addition to these, components needed for the semiconductor device 1 may be prepared. A manufacturing apparatus used for manufacturing the semiconductor device 1 may also be prepared.

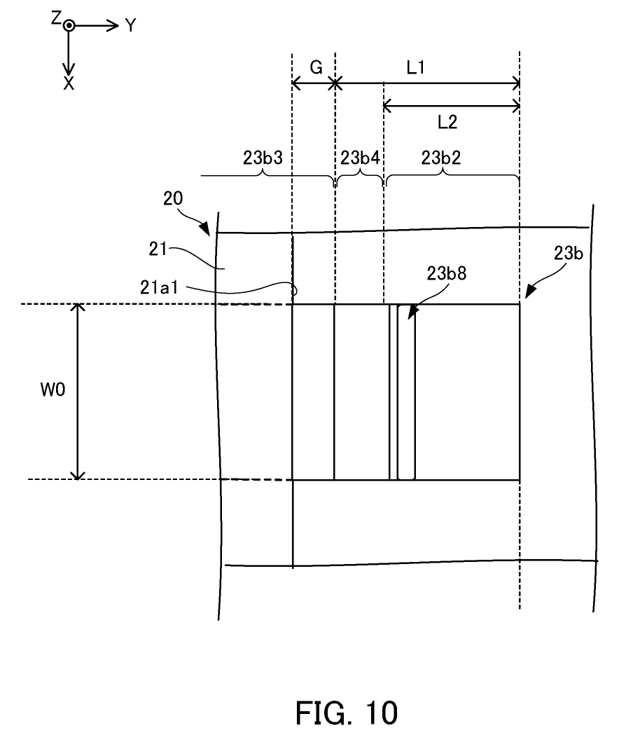

Hereinafter, the second connection terminal 23b of the case 20 prepared in the preparation step will be described with reference to FIGS. 9 and 10. FIG. 9 is a cross-sectional view of a connection terminal included in the case of the semiconductor device according to the embodiment. FIG. 10 is a plan view of the connection terminal included in the case of the semiconductor device according to the embodiment. FIG. 9 corresponds to FIG. 6 illustrating the case 20. FIG. 10 corresponds to FIG. 7 illustrating the case 20.

Although the second connection terminal 23b will be described hereinafter, the same applies to the first connection terminals 22a, 22b, and 22c, the second connection terminals 23a and 23c, the W-phase output terminal 24a, the V-phase output terminal 24b, and the U-phase output terminal 24c.

As described above, the second connection terminal 23b included in the case 20 prepared in the preparation step includes the connection portion 23b1, the bonding portion 23b2, and the wiring portion 23b3 and the rising portion 23b4 integrally provided between the connection portion 23b1 and the bonding portion 23b2.

The notch 23b8 is formed in the upper surface 23b6 of the bonding portion 23b2 before the second connection terminal 23b is bonded to the insulated circuit board 11. The notch 23b8 is formed in the upper surface 23b6 at a position separated by a predetermined length in the +Y direction from the boundary between the bonding portion 23b2 and the rising portion 23b4. The notch 23b8 may be provided in the bonding portion 23b2 of the second connection terminal 23b by, for example, etching or machining. The notch 23b8 crosses the bonding portion 23b2 in parallel to the width direction of the bonding portion 23b2, which is the ±X directions. The width (in the ±X directions) of the notch 23b8 provided by etching or machining may be the width W0 of the bonding portion 23b2 in plan view.

The depth of the notch 23b8 may be, for example, 58% or more and 83% or less of the thickness T of the second connection terminal 23b, as long as the strength of the second connection terminal 23b is maintained at a certain level or more. The thickness of a portion of the second connection terminal 23b, the portion where the notch 23b8 is formed, may be about 1.0 mm. The shape of the notch 23b8 in a side view may be a rectangular shape, an arc shape, or a triangular shape. When the notch 23b8 has a rectangular shape or an arc shape, the ±Y direction length may be, for example, equal to or greater than 1/2 of the thickness T of the second connection terminal 23b and equal to or less than the thickness T of the second connection terminal 23b. Further, in the case of the rectangular shape, the bottom surface in the direction of the lower surface 23b5 may have rounded corner portions.

Next, a semiconductor unit manufacturing step of manufacturing the individual semiconductor unit 10 is performed (step P2 in FIG. 8). First, the semiconductor chip 12b is set on the conductive circuit pattern 11b2 of the insulated circuit board 11 via a bonding member, and the semiconductor chip 12a is set on the conductive circuit pattern 11b1 of the insulated circuit board 11 via a bonding member. Further, the lead frame 13b is set on a main electrode on the front surface of the semiconductor chip 12a and the conductive circuit pattern 11b2 via a bonding member. The lead frame 13a is set on a main electrode on the front surface of the semiconductor chip 12b and the conductive circuit pattern 11b3 via a bonding member.

The insulated circuit board 11, the semiconductor chips 12a and 12b, and the lead frames 13a and 13b thus set are heated to melt the bonding members. The melted bonding member is cured, and the semiconductor chips 12a and 12b are consequently bonded to the conductive circuit patterns 11b1 and 11b2 by the bonding members 14b. The lead frame 13a is bonded to the main electrode of the semiconductor chip 12b and the conductive circuit pattern 11b3 by the bonding member 14c, and the lead frame 13b is bonded to the main electrode of the semiconductor chip 12a and the conductive circuit pattern 11b2 by the bonding member 14c. Thus, the individual semiconductor unit 10 is obtained.

Next, a bonding step of bonding the individual semiconductor unit 10 to the cooling module 3 is performed (step P3 in FIG. 8). The semiconductor units 10a, 10b, and 10c are bonded to the cooling surface 3a of the cooling module 3 via the bonding member 14a along the longitudinal direction of the cooling surface 3a.

Next, a case attachment step of attaching the case 20 to the cooling module 3 is performed (step P4 in FIG. 8). The case 20 is attached to the cooling surface 3a of the cooling module 3 with an adhesive (not illustrated). In this step, the semiconductor units 10a, 10b, and 10c on the cooling surface 3a are stored in the unit storage portions 21e1, 21e2, and 21e3 of the case 20, respectively.

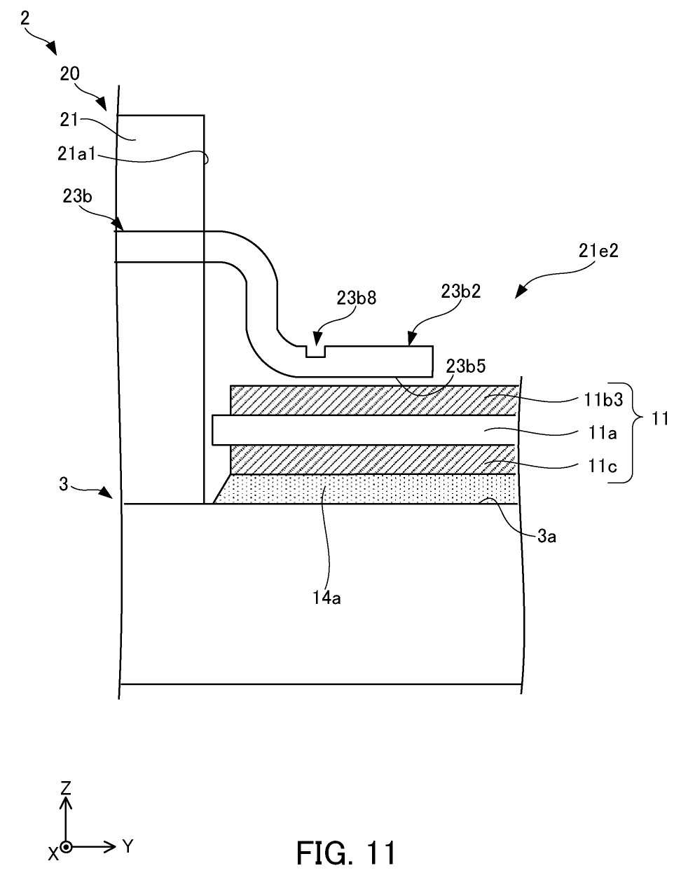

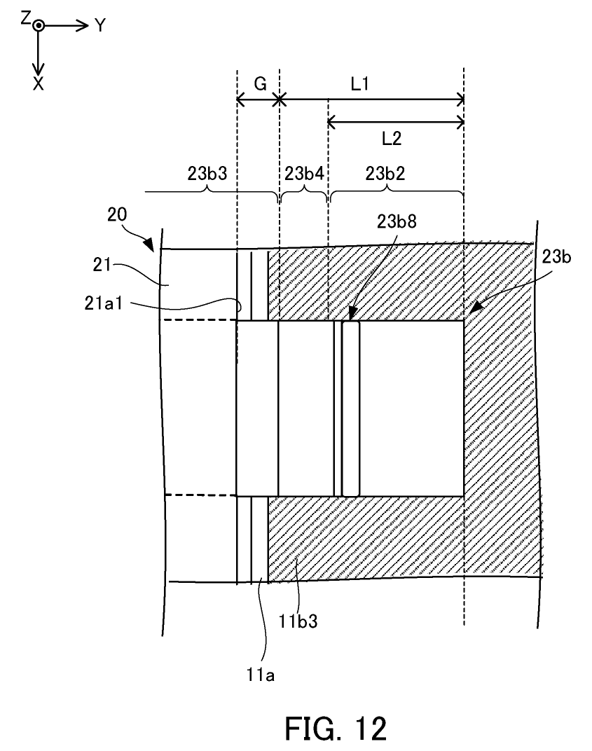

The second connection terminal 23b when the case 20 is attached in this manner will be described with reference to FIGS. 11 and 12. FIG. 11 is a cross-sectional view illustrating a case attachment step in the manufacturing method of the semiconductor device according to the embodiment. FIG. 12 is a plan view illustrating the case attachment step in the manufacturing method of the semiconductor device according to the embodiment.

When the case 20 is attached to the cooling surface 3a of the cooling module 3, as illustrated in FIGS. 11 and 12, the lower surface 23b5 of the bonding portion 23b2 of the second connection terminal 23b faces the conductive circuit pattern 11b3 with a gap therebetween. Each of the bonding portions of the first connection terminals 22a, 22b, and 22c, the second connection terminals 23a and 23c, the W-phase output terminal 24a, the V-phase output terminal 24b, and the U-phase output terminal 24c also faces a corresponding conductive circuit pattern with a gap therebetween.

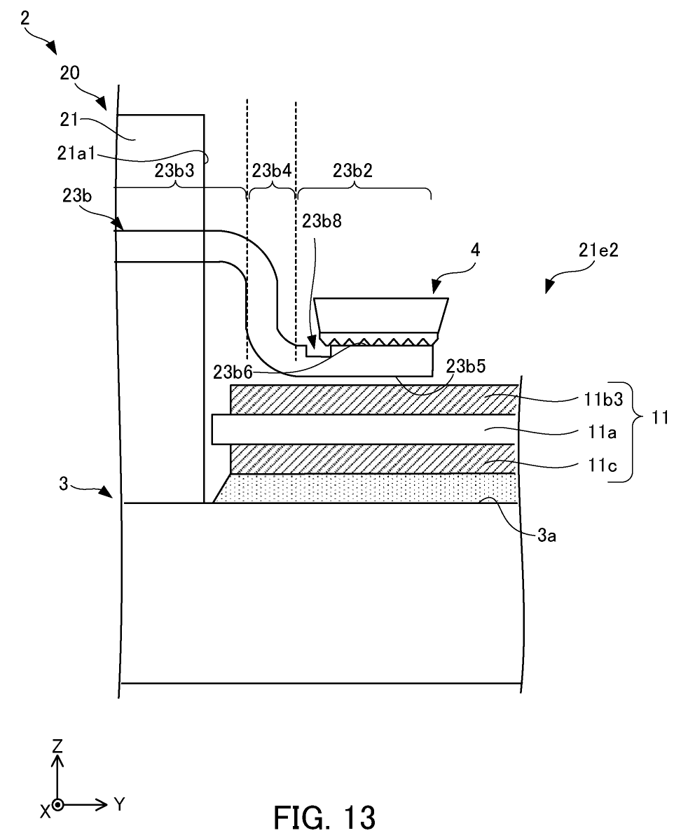

In the case attachment step, a tool 4 of an ultrasonic bonding apparatus is set on the upper surface 23b6 of the bonding portion 23b2 of the second connection terminal 23b. The lower surface 23b5 of the bonding portion 23b2 faces the conductive circuit pattern 11b3. For example, as illustrated in FIG. 13, a plurality of protrusions at the tip of the tool 4 are disposed on the upper surface 23b6 of the bonding portion 23b2 of the second connection terminal 23b. In particular, the tool 4 is disposed on an edge of the notch 23b8, the edge being away from the inner wall 21a1. That is, the tool 4 is disposed on the upper surface 23b6 such that the end portion of the tool 4 protrudes into the notch 23b8.

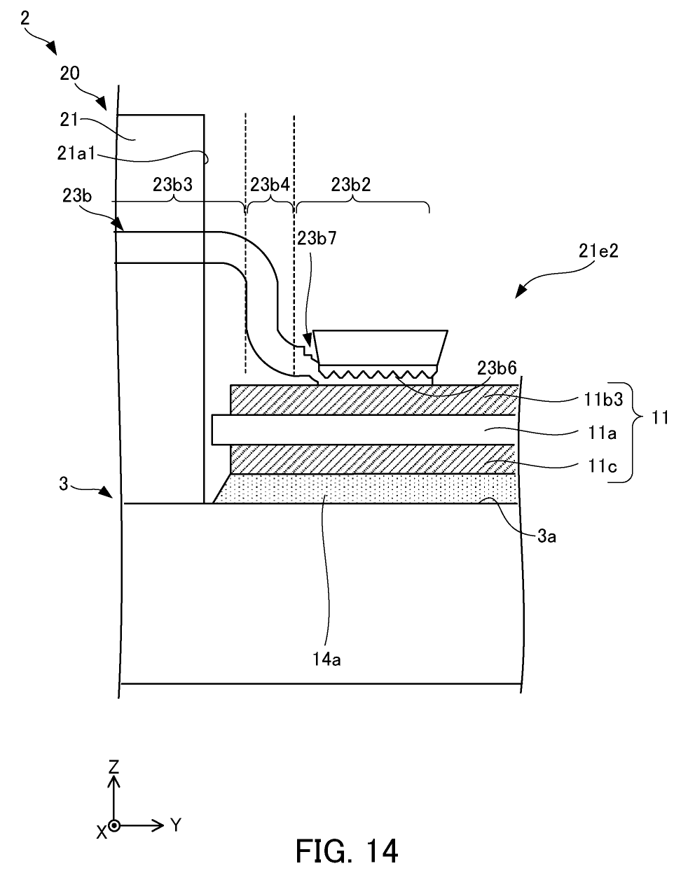

Next, a first wiring step of bonding each of the first connection terminals 22a, 22b, and 22c, the second connection terminals 23a, 23b, and 23c, the W-phase output terminal 24a, the V-phase output terminal 24b, and the U-phase output terminal 24c to a corresponding insulated circuit board 11 is performed (step P5 in FIG. 8). As an example, the bonding of the second connection terminal 23b to the conductive circuit pattern 11b3 of the insulated circuit board 11 will be described with reference to FIGS. 13 and 14. FIG. 13 is a cross-sectional view illustrating the first wiring step (before bonding) in the manufacturing method of the semiconductor device according to the embodiment. FIG. 14 is a cross-sectional view illustrating the first wiring step (during bonding) in the manufacturing method of the semiconductor device according to the embodiment.

The ultrasonic bonding apparatus presses the bonding portion 23b2 against the conductive circuit pattern 11b3 while ultrasonically vibrating the tool 4. As described above, the distance G from the inner wall 21a1 to the rising portion 23b4 of the second connection terminal 23b is 1.2 mm or more and 1.7 mm or less, which is narrow, and the rigidity of the portion corresponding to the distance G of the second connection terminal 23b is high (see FIG. 9). Therefore, since the second connection terminal 23b whose bonding portion 23b2 is pressed by the tool 4 is fixed to the frame portion 21 by the wiring portion 23b3, the portion corresponding to the distance G of the wiring portion 23b3 and the rising portion 23b4 are hardly bent. In the present embodiment, the distance G of each of the first connection terminals 22a, 22b, and 22c and the second connection terminals 23a, 23b, and 23c is smaller than that of each of the W-phase output terminal 24a, the V-phase output terminal 24b, and the U-phase output terminal 24c. Therefore, the first connection terminals 22a, 22b, and 22c and the second connection terminals 23a, 23b, and 23c are less likely to bend than the W-phase output terminal 24a, the V-phase output terminal 24b, and the U-phase output terminal 24c.

On the other hand, the bonding portion 23b2 of the second connection terminal 23b is provided with the notch 23b8. Therefore, the thickness of a portion of the bonding portion 23b2, the portion being provided with the notch 23b8, is less, and the rigidity of this portion is lower than that of the other portion. In addition, the tool 4 is disposed on an edge of the notch 23b8 of the upper surface 23b6 of the bonding portion 23b2, the edge being away from the inner wall 21a1, and presses the notch 23b8. Therefore, this edge of the notch 23b8 is crushed by the tool 4. At the same time, a portion of the bonding portion 23b2, the portion corresponding to the notch 23b8, is bent. As a result, as illustrated in FIG. 14, the lower surface 23b5 of the bonding part 23b9 of the bonding portion 23b2, the bonding part 23b9 having been pressed and crushed by the tool 4, is brought into contact with the conductive circuit pattern 11b3 and is reliably bonded thereto.

The portion of the bonding portion 23b2, the portion having been pressed by the tool 4, expands in the ±X directions. The bonding part 23b9 (the second part 23b9b in FIG. 7) pressed by the tool 4 also expands in the ±X directions. Since this portion has the thickness of the second connection terminal 23b before the pressing, the width becomes the widest width W2 when the second connection terminal 23b is expanded in the ±X directions by the pressing. In addition, the bonding part 23b9 (the first part 23b9a in FIG. 7) of the notch 23b8, the bonding part 23b9 having been pressed by the tool 4, also expands in the ±X directions. Since this portion is thinner than the thickness of the second connection terminal 23b before the pressing, after the portion spreads in the ±X directions, the portion has the width W1 narrower than the width W2 by the pressing.

In addition, although one edge of the notch 23b8 is crushed, the opposite edge of the notch 23b8 is not crushed. Thus, as described above, the low-rigidity part 23b7 having rigidity lower than that of the opposite edge is formed. When the bonding portion 23b2 is pressed to the conductive circuit pattern 11b3, the low-rigidity part 23b7 is bent, and the bonding part 23b9 comes into contact with and is pressed to the conductive circuit pattern 11b3. As described above, the first connection terminals 22a, 22b, and 22c and the second connection terminals 23a, 23b, and 23c are less likely to bend than the W-phase output terminal 24a, the V-phase output terminal 24b, and the U-phase output terminal 24c. Therefore, in order to further reduce the rigidity of the first connection terminals 22a, 22b, and 22c and the second connection terminals 23a, 23b, and 23c, the depth of the notch 23b8 may be set greater than the depth of the notch 23b8 provided in the W-phase output terminal 24a, the V-phase output terminal 24b, and the U-phase output terminal 24c.

When the tool 4 is removed, as illustrated in FIG. 6, indentations are transferred to the upper surface 23b6 of the bonding portion 23b2 of the second connection terminal 23b, and the bonding part 23b9 of the bonding portion 23b2, the bonding part 23b9 corresponding to the indentations, is bonded to the conductive circuit pattern 11b3. The configuration of the second connection terminal 23b at this time is as described above. Similarly, each of the bonding portions of the first connection terminals 22a, 22b, and 22c, the second connection terminals 23a and 23c, the W-phase output terminal 24a, the V-phase output terminal 24b, and the U-phase output terminal 24c is also bonded to a corresponding conductive circuit pattern in the same way.

Next, a second wiring step of execute wiring by wire bonding is performed (step P6 in FIG. 8). The control electrodes of the semiconductor chips 12a and 12b and the control terminals 25a, 25b, and 25c are connected by the wires 26 by a bonding tool.

Next, a sealing step of sealing the inside of the unit storage portions 21e1, 21e2, and 21e3 with a sealing member is performed (step P7 in FIG. 8). After filling the unit storage portions 21e1, 21e2, and 21e3 with the sealing member, the sealing member is heated and cured to seal the insulated circuit board 11, the semiconductor chips 12a and 12b, the lead frames 13a and 13b, and the wires 26. At this time, the gap between the bonding portion 23b2 of the second connection terminal 23b and the conductive circuit pattern 11b3 is also sealed by the sealing member. Thus, the semiconductor device 1 is obtained.

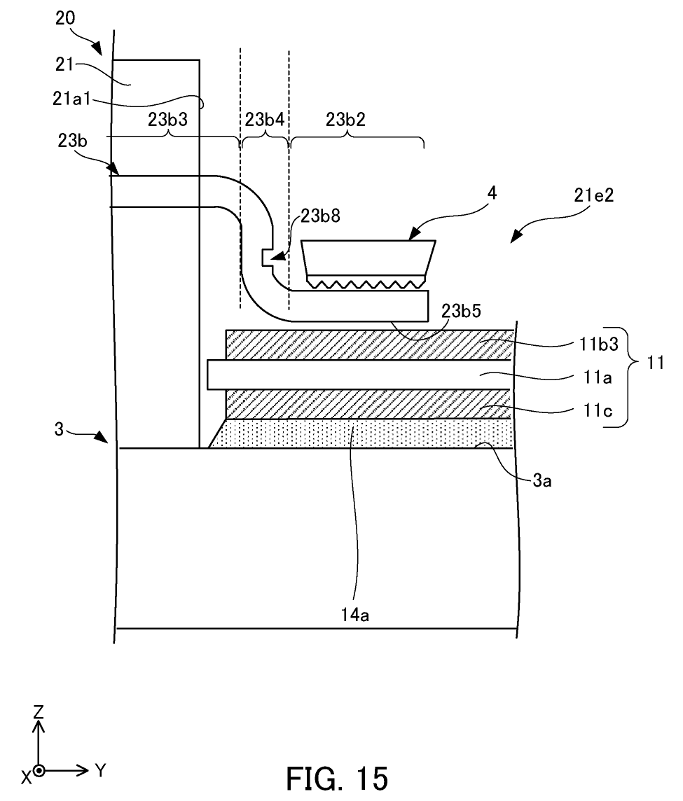

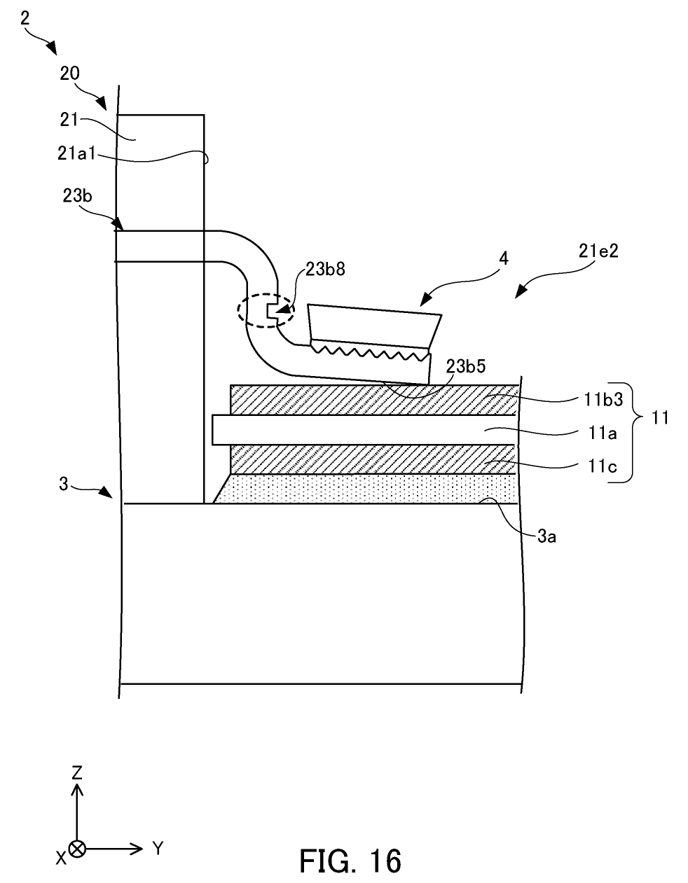

Hereinafter, a second connection terminal 23b according to a reference example will be described. In the above embodiment, by forming the notch 23b8 in the second connection terminal 23b, the rigidity of that portion is reduced so that ultrasonic bonding is performed. According to the reference example, a case where the notch 23b8 is formed at a position different from that according to the embodiment will be described with reference to FIGS. 15 and 16. FIG. 15 is a cross-sectional view (before bonding) illustrating a first wiring step in a manufacturing method of a semiconductor device according to the reference example. FIG. 16 is a cross-sectional view (during bonding) illustrating the first wiring step in the manufacturing method of the semiconductor device according to the reference example.

According to the reference example, the notch 23b8 is formed near the bonding portion 23b2 and on the +Y direction surface of the rising portion 23b4 of the second connection terminal 23b (see FIG. 15). A case where the second connection terminal 23b according to the reference example is bonded to the conductive circuit pattern 11b3 by ultrasonic bonding as in the step P5 (first wiring step) in FIG. 8 will be described. The semiconductor device according to the reference example is also manufactured according to the manufacturing method in FIG. 8. Hereinafter, the step P5 will be described.

As illustrated in FIG. 15, the tool 4 of the ultrasonic bonding apparatus is set on the upper surface 23b6 of the bonding portion 23b2 of the second connection terminal 23b. The lower surface 23b5 of the bonding portion 23b2 faces the conductive circuit pattern 11b3. The ultrasonic bonding apparatus presses the bonding portion 23b2 against the conductive circuit pattern 11b3 while ultrasonically vibrating the tool 4. In this case, the rigidity of the portion of the notch 23b8 of the second connection terminal 23b is lower than that of the other portion. For this reason, the portion of the rising portion 23b4 of the second connection terminal 23b, the portion including the notch 23b8 (the portion corresponding to a low-rigidity part), is bent. That is, as illustrated in FIG. 16, the portion of the rising portion 23b4 of the second connection terminal 23b, the portion including the notch 23b8, serves as a fulcrum, and the portion located below this portion rotates toward the conductive circuit pattern 11b3. As a result, the bonding portion 23b2 is inclined. Therefore, the +Y direction side of the lower surface 23b5 of the bonding portion 23b2 comes into contact with the conductive circuit pattern 11b3. Although the tip end portion of the lower surface 23b5 of the bonding portion 23b2 is bonded to the conductive circuit pattern 11b3, the entire lower surface 23b5 of the bonding portion 23b2 is not bonded to the conductive circuit pattern 11b3. In this case, the width of the tip end side of the bonding portion 23b2 is wider in the ±X directions than the other portion. Therefore, the bonding portion 23b2 is not reliably bonded to the conductive circuit pattern 11b3.

The semiconductor device 1 includes the conductive circuit pattern 11b3, the case 20 having a frame shape in plan view and including the inner wall 21a1 surrounding the unit storage portion 21e2 (the opening 21e) for storing the conductive circuit pattern 11b3, and the second connection terminal 23b having a portion fixed to the case 20, extending in the extending direction from the inner wall 21a1 to the unit storage portion 21e2, and including the bonding portion 23b2 having the lower surface 23b5 bonded to the conductive circuit pattern 11b3 and the upper surface 23b6 with indentations. The bonding portion 23b2 of the second connection terminal 23b includes the bonding part 23b9 having the indentations on the upper surface 23b6 and the low-rigidity part 23b7 adjacent to the bonding part 23b9 in the direction of the inner wall 21a1. Further, the thickness of the bonding portion 23b2 decreases in the order of the low-rigidity part 23b7 and the bonding part 23b9 in the extending direction from the inner wall 21a1, and the width of the bonding portion 23b2 is largest at the bonding part 23b9 in plan view.

In the semiconductor device 1, the thickness of the low-rigidity part 23b7 of the bonding portion 23b2 of the second connection terminal 23b is less, and thus the rigidity is lower than that of the other portion. Therefore, the bonding portion 23b2 of the second connection terminal 23b is bent at the low-rigidity part 23b7, and the bondability to the conductive circuit pattern 11b3 is reliably improved. Therefore, the second connection terminal 23b is less likely to peel off from the conductive circuit pattern 11b3, and a decrease in the reliability of the semiconductor device 1 is suppressed.

In the manufacture of the semiconductor device 1 according to the above-described embodiment, when the bonding portion 23b2 of the second connection terminal 23b is pressed by the tool 4, the tool 4 is disposed on an edge of the notch 23b8 of the upper surface 23b6 of the bonding portion 23b2. As a result, the rigidity of the portion of the notch 23b8 of the bonding portion 23b2 is reduced, and the portion is pressed reliably. The tool 4 may be disposed on a different portion of the upper surface 23b6. For example, the tool 4 may be disposed on a portion other than the above-described edge of the notch 23b8. The tool 4 may be disposed on a portion away from the notch 23b8 in the +Y direction. Even if the tool 4 is separated from the notch 23b8 to some extent, since the rigidity of the portion of the notch 23b8 of the bonding portion 23b2 is reduced, the portion of the bonding portion 23b2, the portion having been pressed by the tool 4, is bonded to the conductive circuit pattern 11b3. The bonded portion 23b2 bonded in this manner maintains the notch 23b8, and the bonding part 23b9 is formed away from the notch 23b8 in the +Y direction.

However, when the tool 4 presses a portion too far from the notch 23b8, the bonding portion 23b2 may fail to bend appropriately at the portion of the notch 23b8. Therefore, in order to reliably bend the bonding portion 23b2 at the notch 23b8, it is preferable that the tool 4 be separated from the notch 23b8, for example, by about the thickness of the portion of the notch 23b8 of the bonding portion 23b2.

According to the disclosed technique, the bondability of a terminal to a conductive plate is improved.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a case having a frame shape in a plan view of the semiconductor device, an inner surface of the case surrounding a storage area;
a conductive plate disposed in the storage area; and
a terminal extending in an extending direction from the case to the storage area, the terminal having
a connection portion fixed to the case, and
a bonding portion bonded to the conductive plate, wherein
the bonding portion includes:
a bonding part having indentations on an upper surface thereof, and
a low-rigidity part adjacent to the bonding part, the low-rigidity part being located between the bonding part and the inner surface,
a thickness of the bonding portion decreases at the low-rigidity part and further decreases at the bonding part in the extending direction, and
in the plan view, the bonding part has a width larger than a width of a remaining portion of the bonding portion excluding the bonding part.

2. The semiconductor device according to claim 1, wherein the bonding part includes:
a first part that has a first width in the plan view, and
a second part that has a second width in the plan view,
in the extending direction, the first part being closer to the inner surface than the second part, the second width being larger than the first width.

3. The semiconductor device according to claim 2, wherein the first width is larger than the width of the remaining portion of the bonding portion excluding the bonding part.

4. The semiconductor device according to claim 3,
wherein the remaining portion of the bonding portion is located above the bonding part, and
wherein the low-rigidity part is inclined toward the bonding part.

5. The semiconductor device according to claim 1,
wherein the bonding portion has, in the extending direction, a first end and a second end, the first end being located closer to the inner surface than the second end,
wherein the terminal further includes
a wiring portion having, in the extending direction, a first end fixed to the case and a second end extending to the storage area, and
a rising portion connecting the first end of the bonding portion and the second end of the wiring portion, and
wherein in the extending direction, a shortest distance from the inner surface to the rising portion is 1.0 mm or more and 2.0 mm or less.

6. The semiconductor device according to claim 1,
wherein the bonding portion has, in the extending direction, a first end and a second end, the first end being located closer to the inner surface than the second end,
wherein the terminal further includes
a wiring portion having, in the extending direction, a first end fixed to the case and a second end extending to the storage area, and
a rising portion connecting the first end of the bonding portion and the second end of the wiring portion,
the rising portion having a concave curved surface in a side view of the semiconductor device, and
wherein the low-rigidity part has an edge, which is located within a range of 1 mm or less in the extending direction from an end of the curved surface.

7. The semiconductor device according to claim 6, wherein the low-rigidity part has a lower surface that is spaced apart from the conductive plate.

8. The semiconductor device according to claim 1, wherein the low-rigidity part has a thickness that is 58% or more and 83% or less of a thickness of the terminal excluding the bonding portion.

9. The semiconductor device according to claim 1, wherein a gap is formed between a lower surface of the low-rigidity part of the bonding portion of the terminal and the conductive plate.

10. The semiconductor device according to claim 1, wherein the terminal is a positive electrode terminal or a negative electrode terminal.

11. A semiconductor device manufacturing method, comprising:
preparing
a conductive plate, and
a case having a frame shape, an inner surface of the case surrounding a storage area, and
a terminal extending in an extending direction from the inner surface of the case toward the storage area, the terminal including a bonding portion having a lower surface and an upper surface having a notch formed therein, the bonding portion having a first side and a second side, the first side being closer to the inner surface of the case than the second side in the extending direction, the notch having an edge located on the second side of the bonding portion;
placing the conductive plate facing the lower surface of the bonding portion in the storage area of the case; and
pressing an area of the upper surface of the bonding portion, the area being from the edge of the notch to the second side of the bonding portion.

12. The semiconductor device manufacturing method according to claim 11, wherein the pressed area of the upper surface of the bonding portion includes the edge of the notch in the upper surface of the bonding portion.
